(19) United States
(12) Patent Application Publication
(10) Pub. No.: US 2011/0232572 A1
(43) Pub. Date: Sep. 29, 2011

(54) PLASMA FILM-COATING APPARATUS

(75) Inventor: SHAO-KAI PEI, Tu-Cheng (TW)

(73) Assignee: HON HAI PRECISION INDUSTRY CO., LTD., Tu-Cheng (TW)

(21) Appl. No.: 12/820,057

(22) Filed: Jun. 21, 2010

(30) Foreign Application Priority Data
Mar. 29, 2010 (TW) 99109340

(51) Int. Cl. C23C 16/50

(52) U.S. Cl. 118/723 ER

(57) ABSTRACT

An exemplary plasma film-coating apparatus includes a reaction chamber, a pipe, and a reaction device. The reaction chamber defines a reaction cavity. The reaction cavity includes receiving grooves defined in an inner wall of the reaction chamber. The receiving grooves are configured for receiving workpieces. The pipe extends through the reaction chamber and is in communication with the reaction cavity. The reaction device is rotatably connected to the reaction chamber. The reaction device includes two electrodes and at least one precursor chamber. The two electrodes are positioned inside the reaction cavity, and face each other. The at least one precursor chamber is attached to a surface of one electrode away from another electrode, and extends through the reaction chamber. The at least one precursor chamber is in communication with the reaction cavity and is configured for providing gaseous precursor.

### BACKGROUND

1. Technical Field

The present disclosure relates to plasma film-coating apparatuses.

2. Description of Related Art

Plasma film-coating apparatuses typically include a reaction chamber and two electrodes positioned in the reaction chamber; and the electrodes are arranged opposite to each other. Workpieces to be coated are placed on an electrode. During the coating process, plasma is induced in an electric field between the two electrodes inside the reaction chamber, and then reaction gas is introduced into the reaction chamber to react with the plasma. Finally, the resultant materials of the reaction are coated onto the workpieces.

However, because the workpieces are placed on the electrode, thus during the coating process, the plasma may damage the thin film which has already been coated on the workpieces.

Therefore, a plasma film-coating apparatus, which can overcome the above-mentioned problems, is needed.

### BRIEF DESCRIPTION OF THE DRAWINGS

FIG. 1 is an isometric and schematic view of a plasma film-coating apparatus, according to an exemplary embodiment.

FIG. 2 is a partially disassembled view of the plasma film-coating apparatus of FIG. 1.

FIG. 3 is a sectional view of the plasma film-coating apparatus of FIG. 1.

### DETAILED DESCRIPTION

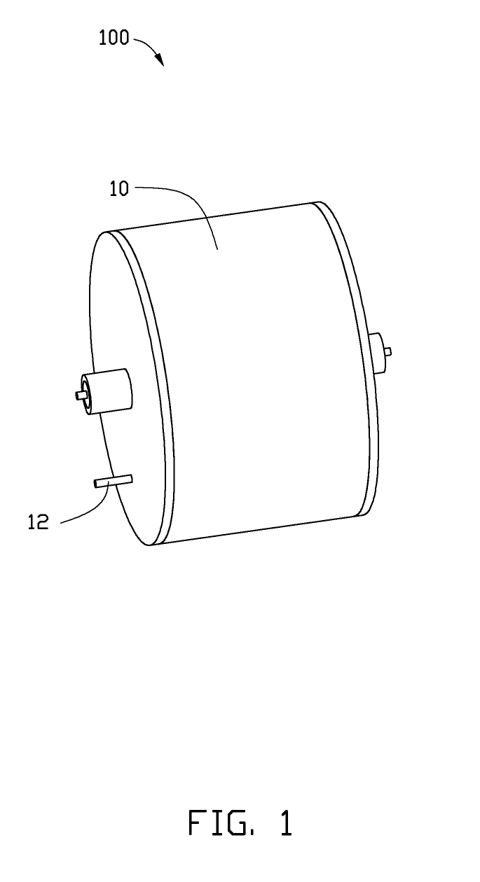

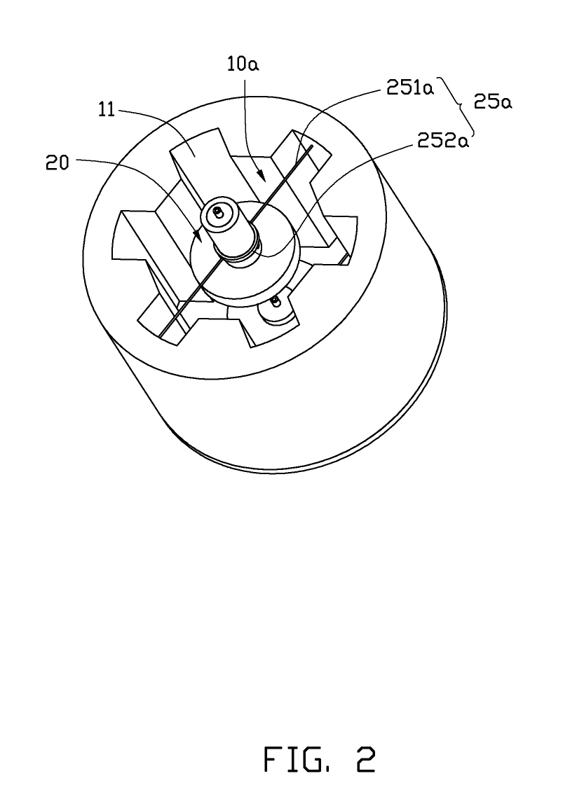

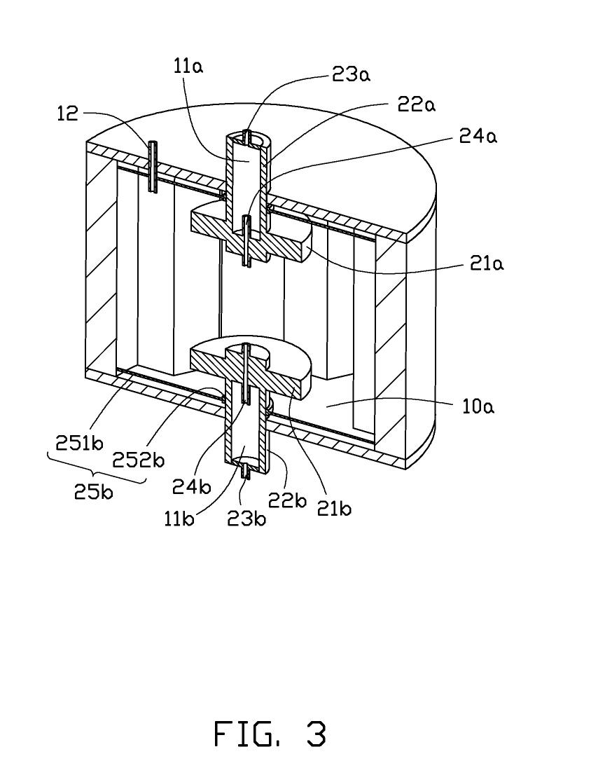

Referring to FIGS. 1-3, a plasma film-coating apparatus 100, according to an exemplary embodiment, includes a reaction chamber 10, and a reaction device 20 rotatably connected to the reaction chamber 10.

The reaction chamber 10 is substantially a cylinder and defines a reaction cavity 10a therein. The reaction cavity 10a includes a plurality of receiving grooves 11 configured for receiving a plurality of workpieces (not shown). The receiving grooves 11 are defined in an inner wall of the reaction chamber 10 and are extended along the central axis of the reaction chamber 10. Therefore, the workpieces received in the receiving grooves 11 are attached to the inner wall of the reaction chamber 10. A pipe 12 extends through the reaction chamber 10 and is in communication with the reaction cavity 10a. The pipe 12 is configured for introducing a reaction gas. The pipe 12 is arranged at close proximity to the inner wall of the reaction chamber 10 in the receiving groove 11.

The reaction device 20 includes a first electrode 21a, a second electrode 21b, a first precursor chamber 22a, and a second precursor chamber 22b. The first precursor chamber 22a, the first electrode 21a, the second electrode 21b, and the second precursor chamber 22b are arranged in such order along the central axis of the reaction chamber 10.

The first electrode 21a and the second electrode 21b are positioned inside the reaction cavity 10a and are facing each other. The first precursor chamber 22a extends from and is attached to a surface of the first electrode 21a away from the second electrode 21b. The first precursor chamber 22a defines a first precursor cavity 11a. The first precursor chamber 22a rotatably extends through the reaction chamber 10. The first precursor chamber 22a is configured for providing a gaseous precursor into the reaction chamber 10. For example, a solid precursor may be placed inside the first precursor chamber 22a, and during the coating process, the solid precursor is heated by a heater (not shown) in the first precursor chamber 22a to become the gaseous precursor. In this embodiment, the first precursor chamber 22a is integrally formed with the first electrode 21a.

A first opening 23a and a second opening 24a are respectively defined in opposite ends of the first precursor chamber 22a. The first opening 23a is configured for introducing a gas into the first precursor cavity 11a. The second opening 24a is configured for introducing the gas from the first precursor cavity 11a into the reaction cavity 10a. The second opening 24a runs through the first electrode 21a.

Configurations of the second electrode 21b and the second precursor chamber 22b are the same as those of the first electrode 21a and the first precursor chamber 22a. The second precursor chamber 22b defines a second precursor cavity 11b.

The film-coating apparatus 100 further includes a first support 25a and a second support 25b. The first support 25a includes a first supporting rod 251a and a first bearing 252a. The first supporting rod 251a is fixed to the first bearing 252a and to the inner wall of the reaction chamber 10. The first precursor chamber 22a rotatably extends through the first bearing 252a. Configuration of the second support 25b is the same as that of the first support 25a. A second supporting rod 251b of the second support 25b is fixed to a second bearing 252b of the second support 25b and to the inner wall of the reaction chamber 10. The second precursor chamber 22b rotatably extends through the second bearing 252b. When a torque is applied to the reaction chamber 10, the reaction chamber 10 rotates relative to the first and second precursor chambers 22a, 22b and the first and second electrodes 21a, 21b.

During the coating process, the solid precursors inside the first and second precursor cavities 11a, 11b are vaporized by heat, and then carrier gas is introduced through the first opening 23a and a third opening 23b defined at an end of the second precursor chamber 22b to bring the gaseous precursors into the reaction cavity 10a. Then, the carrier gas together with the gaseous precursors enters into the reaction cavity 10a between the first and second electrodes 21a, 21b using the second opening 24a and a fourth opening 24b defined at another end of the second precursor chamber 22b. The carrier gas becomes plasma in an electric field generated between the first and second electrodes 21a, 21b. The plasma reacts with the gaseous precursor to make the gaseous precursor generate a plurality of ions. Meanwhile, the reaction gas is introduced into the reaction cavity 10a using the pipe 12. The reaction gas reacts with the ions in the electric field. The resultant material of the reaction is then deposited onto the workpieces. Furthermore, during the reaction between the reaction gas and the ions, the reaction chamber 10 along with the workpieces inside may be driven to rotate, so that the workpieces received in the receiving grooves 11 can be coated uniformly.

Since the workpieces are positioned out of the electric field between the first and the second electrodes 21a, 21b, the plasma does not easily impinge on the workpieces. Therefore, the film which has been coated on the workpieces is protected. Furthermore, the reaction chamber 10 along with the workpieces can be driven to rotate, and the workpieces received in the receiving grooves 11 can be coated uniformly.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A plasma film-coating apparatus, comprising:
a reaction chamber defining a reaction cavity, the reaction cavity comprising a plurality of receiving grooves defined in an inner wall of the reaction chamber, the receiving grooves being configured for receiving a plurality of workpieces;
a pipe extending through the reaction chamber and in communication with the reaction cavity; and
a reaction device rotatably connected to the reaction chamber, the reaction device comprising two electrodes and at least one precursor chamber, the two electrodes positioned inside the reaction cavity and facing each other, the at least one precursor chamber attached to a surface of one electrode away from another electrode and extending through the reaction chamber, the at least one precursor chamber being in communication with the reaction cavity and configured for providing a gaseous precursor.

2. The plasma film-coating apparatus of claim 1, wherein the at least one precursor chamber comprises a first precursor chamber and a second precursor chamber, the two electrodes comprising a first electrode and a second electrode, the first precursor chamber attached to a surface of the first electrode away from the second electrode, and the second precursor chamber attached to a surface of the second electrode away from the first electrode.

3. The plasma film-coating apparatus of claim 2, wherein the first precursor chamber defines a first precursor cavity, and the plasma film-coating apparatus further comprises a first opening and a second opening defined in opposite ends of the first precursor chamber, the first opening is configured for introducing a gas into the first precursor cavity, the second opening is configured for introducing the gas from the first precursor cavity into the reaction cavity.

4. The plasma film-coating apparatus of claim 2, wherein the second precursor chamber defines a second precursor cavity, and the plasma film-coating apparatus further comprises a third opening and a fourth opening defined in opposite ends of the second precursor chamber, wherein the third opening is configured for introducing a gas into the second precursor cavity, the fourth opening is configured for introducing gas from the second precursor cavity into the reaction cavity.

5. The plasma film-coating apparatus of claim 2, wherein the first electrode is integrally formed with the first precursor chamber, and the second electrode is integrally formed with the second precursor chamber.

6. The plasma film-coating apparatus of claim 2, further comprising a first support and a second support, wherein the first precursor chamber rotatably extending through the first support, and the second precursor chamber rotatably extending through the second support.

7. The plasma film-coating apparatus of claim 6, wherein the first support comprises a first supporting rod and a first bearing, the first supporting rod being fixed to the first bearing and to the inner wall of the reaction chamber, and the first precursor chamber rotatably extending through the first bearing.

8. The plasma film-coating apparatus of claim 6, wherein the second support comprises a second supporting rod and a second bearing, the second supporting rod being fixed to the second bearing and to the inner wall of the reaction chamber, and the second precursor chamber rotatably extending through the second bearing.
